(19) United States
(12) Patent Application Publication
(10) Pub. No.: US 2012/0242389 A1
(43) Pub. Date: Sep. 27, 2012

(54) SENSOR CONTROL CIRCUIT AND SENSOR SYSTEM

(75) Inventors: Toru Sato, Yokohama-Shi (JP); Maho Kuwahara, Tokyo (JP); Yosuhiro Hayashi, Yokohama-Shi (JP)

(73) Assignee: KABUSHIKI KAISHA TOSHIBA, Tokyo (JP)

(21) Appl. No.: 13/237,042

(22) Filed: Sep. 20, 2011

(30) Foreign Application Priority Data
Mar. 25, 2011 (JP) 2011-68713

(51) Int. Cl. H03L 5/00

(52) U.S. Cl. 327/306

(57) ABSTRACT

A sensor control circuit according to the present embodiment is provided with an autonomous-oscillation loop part configured to generate a sensor-modulated signal having a carrier signal and an alternating signal output by a sensor and superposed on the carrier signal having the same frequency as the alternating signal, and an amplitude adjustment loop part configured to generate a control signal for amplitude adjustment of the carrier signal, by digital processing of a result of comparison between the carrier signal and a reference voltage level. The autonomous-oscillation loop part includes an amplifier configured to perform amplitude adjustment of the carrier signal, and a switched capacitor having a switch configured to be switched by the control signal, the switched capacitor configured to be capable of controlling a gain of the amplifier in accordance with a switching frequency of the switch.

### CROSS REFERENCE TO RELATED APPLICATIONS

This application is based upon and claims the benefit of priority from the prior Japanese Patent Application No. 2011-68713, filed on Mar. 25, 2011, the entire contents of which are incorporated herein by reference.

### FIELD

Embodiments of the present invention relate to a sensor control circuit and a sensor system for a sensor that outputs an alternating current signal.

### BACKGROUND

A representative of resonant sensors that output an alternating current signal is an angular velocity sensor (a gyro sensor). An AGC (Automatic Gain Control) circuit is essential for constant detection sensitivity of the angular velocity sensor.

A resonant frequency of angular velocity sensors is several ten kHz. The control band of an AGC circuit is lower than that because the AGC circuit performs control for constant amplitude. A known AGC circuit is configured with an analog circuit using a CR time constant. The known AGC circuit requires a capacitor with a large capacitance for control in a low-frequency band. Therefore, the known AGC circuit requires a huge chip area in order to fabricate such a capacitor on a semiconductor substrate. Furthermore, implementation of the capacitor as a discrete part requires a terminal to which the capacitor is externally connected and also requires a place on which the capacitor is mounted.

Still furthermore, a resonant loop in an angular velocity sensor requires high linearity in a wide dynamic range which is difficult to achieve with a CMOS variable resistor.

### BRIEF DESCRIPTION OF THE DRAWINGS

FIG. 1 is a block diagram schematically showing the configuration of a sensor system 1 according to an embodiment of the present invention;

FIG. 2(a) shows a circuit diagram of a basic switched capacitor 13a and FIG. 2(b) shows a circuit diagram of a switched capacitor 13 of the present embodiment;

FIG. 3 is a block diagram of a sensor system la that is a comparative example to the sensor system 1 of FIG. 1;

FIG. 4 is a block diagram showing more in detail the internal configuration of an AGC part 2 of FIG. 1;

FIGS. 5(a), 5(b), and 5(c) show signal waveforms in the case where the amplitude of a carrier signal is equal to, smaller than, and larger than a specific value, respectively; and

FIG. 6 is a block diagram showing an example of the internal configuration of a DLPF 24.

### DETAILED DESCRIPTION

Embodiments will now be explained with reference to the accompanying drawings.

A sensor control circuit according to the present embodiment is provided with an autonomous-oscillation loop part configured to generate a sensor-modulated signal having a carrier signal and an alternating signal output by a sensor and superposed on the carrier signal having the same frequency as the alternating signal, and an amplitude adjustment loop part configured to generate a control signal for amplitude adjustment of the carrier signal, by digital processing of a result of comparison between the carrier signal and a reference voltage level. The autonomous-oscillation loop part includes an amplifier configured to perform amplitude adjustment of the carrier signal, and a switched capacitor having a switch configured to be switched by the control signal, the switched capacitor configured to be capable of controlling a gain of the amplifier in accordance with a switching frequency of the switch.

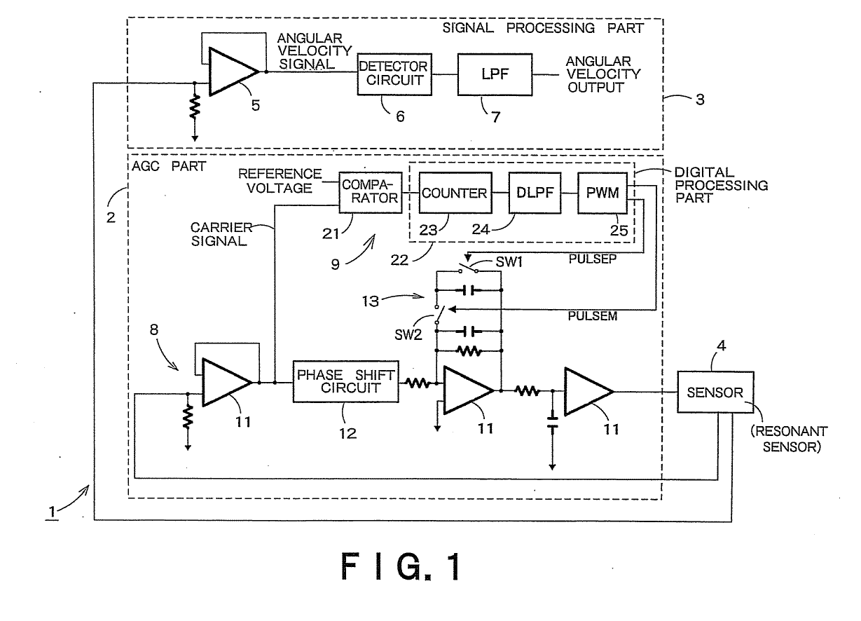

FIG. 1 is a block diagram schematically showing the configuration of a sensor system 1 according to an embodiment of the present invention. The sensor system 1 of FIG. 1 is roughly divided into an AGC part 2, a signal processing part 3, and a sensor 4. The AGC part 2 and the signal processing part 3 can be formed into semiconductor chips, respectively. The AGC part 2 and the signal processing part 3 may be formed into a single semiconductor chip or separate chips. In contrast, the sensor 4 is provided separately from the AGC part 2 and the signal processing part 3.

The sensor 4 is a so-called resonant (vibration) sensor that outputs alternating current signals. The object to be sensed by the sensor 4 is not limited to any particular one. The sensor 4 of the present embodiment is, for example, an angular velocity sensor 4 for detecting an angular velocity.

The AGC part 2 generates a sensor-modulated signal composed of a constant-amplitude carrier signal and an alternating-current sensor-detected signal output from the sensor 4 and superposed on the carrier signal. The sensor-detected signal and the carrier signal may not always be in phase to each other. The sensor-detected signal that is out of phase, for example, by 90 degrees to the carrier signal is superposed thereon to generate a sensor-modulated signal.

The signal processing part 3 has a buffer 5, a detector circuit 6 for removing the carrier signal from the sensor-modulated signal, and a low-pass filter (LPF) 7 that removes a high frequency component contained in an output signal of the detector circuit 6. The sensor-detected signal is taken out as the output of the LPF 7. The sensor-detected signal is, for example, an angular velocity signal when it is detected by an angular velocity sensor 4.

The AGC part 2 has an autonomous-oscillation loop part 8 and an automatic adjustment loop part 9. The autonomous-oscillation loop part 8 performs a process of generating a carrier signal having the same frequency as the sensor-detected signal output from the sensor 4. The automatic adjustment loop part 9 performs feedback control with digital processing of a result of comparison between the carrier signal and a reference voltage level so that the carrier signal has a constant amplitude.

The autonomous-oscillation loop part 8 has a plurality of stages of cascade-connected buffers 11, a phase shift circuit 12, and the sensor 4, connected to one another in a ring shape. Connected to at least one of the plural stages of buffers 11 is a switched capacitor 13. Switches SW1 and SW2 of the switched capacitor 13 are turned on or off to adjust the gain of the buffer 11 connected to the switched capacitor 13. The buffer 11 connected to the switched capacitor 13 corresponds to an amplifier for amplitude adjustments of the carrier signal.

The automatic adjustment loop part 9 has a comparator 21 and a digital processing part 22. The switches SW1 and SW2 of the switched capacitor 13 are turned on or off by a control signal output from the digital processing part 22.

The digital processing part 22 has a counter 23, a digital low-pass filter (DLPF) 24, and a pulse-width control circuit (PWM circuit) 25.

The comparator 21 compares the carrier signal and the reference voltage level. Based on a result of comparison at the comparator 23, the counter 23 counts up while the amplitude of the carrier signal is equal to or higher than the reference voltage level whereas counts down while the former is smaller than the latter, thus generating a count value.

The DLPF 24 smoothes the count value for a specific period to generate a digital smoothed signal. Based on the digital smoothed signal, the PWM circuit 25 generates a control signal for switching control of the switches SW1 and SE2 of the switched capacitor 13.

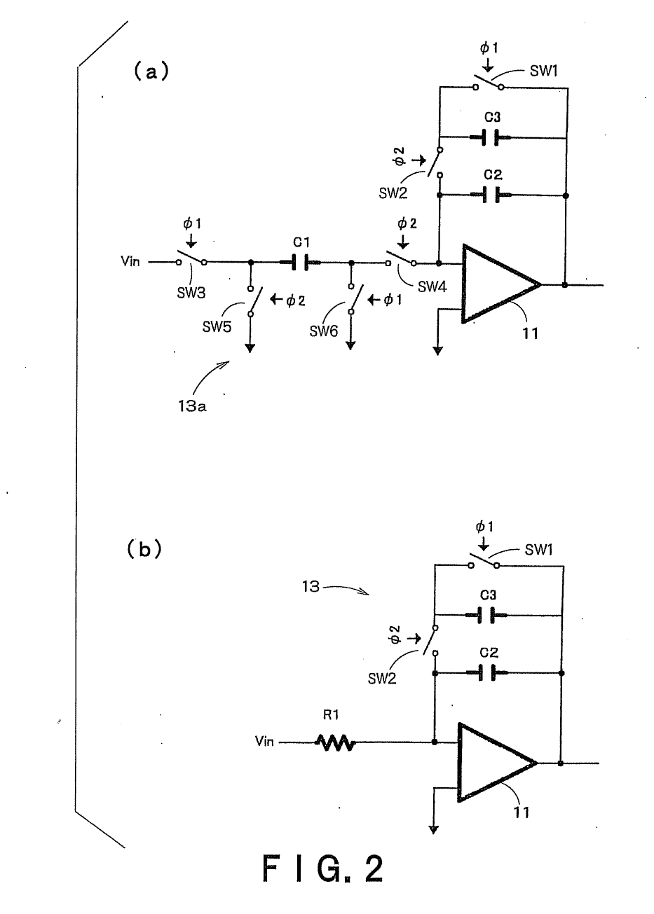

One of the technical features of the present embodiment lies in the switched capacitor 13 for gain adjustments of the buffer 11. The switched capacitor 13 of the present embodiment is different in configuration from a basic switched capacitor 13a. FIG. 2(a) shows a circuit diagram of the basic switched capacitor 13a. FIG. 2(b) shows a circuit diagram of the switched capacitor 13 of the present embodiment. The configuration of the switched capacitor 13 such as shown in FIG. 1 is little bit different from FIG. 2(b), in the strict sense. Nevertheless, the switched capacitor 13 according to the present embodiment will be explained with FIG. 2(b) hereinbelow.

The basic switched capacitor 13a of FIG. 2(a) has a switch SW3, a capacitor C1, and a switch SW4 series-connected between a signal input terminal and an input terminal of the buffer 11, a switch SW5 connected between an end of the capacitor C1 and a ground terminal, a switch SW6 connected between the other end of the capacitor C1 and the ground terminal, and switches SW1 and SW2, and capacitors C2 and C3 connected between the input terminal and a signal output terminal of the buffer 11.

Electrical characteristics of the basic switched capacitor 13a of FIG. 2(a) can be determined with a capacitance ratio of the capacitors C1 to C3.

By contrast, the switched capacitor 13 according to the present embodiment has a resistor R1 only between a signal input terminal and an input terminal of the buffer 11 as shown in FIG. 2(b), without switches SW3 to SW6 and a capacitor C1 such as shown in FIG. 2(a). With the switched capacitor 13 having the resistor R1 only connected to the input terminal of the buffer 11, the buffer 11 can exhibit frequency-dependent gains. In more detail, the gain of the buffer 11 can be controlled in accordance with a switching frequency f of the switches SW1 and SW2.

Given an impedance R for the circuit portion constituted by the switches SW1 and SW2, and the capacitor C3 in FIG. 2(b), the following expression (1) is established.

R=1/(fC2) (1)

A gain G of the buffer 11 in FIG. 2(b) is expressed by the following expression (2).

G=(R/R1) (2)

According to these expressions, a higher switching frequency f of the switches SW1 and SW2 gives a lower impedance R and hence a lower gain G.

As described above, it is understood that the gain G can be set to any value by varying the switching frequency f. In the present embodiment, the switching frequency f is controlled to adjust the gain G of the buffer 11.

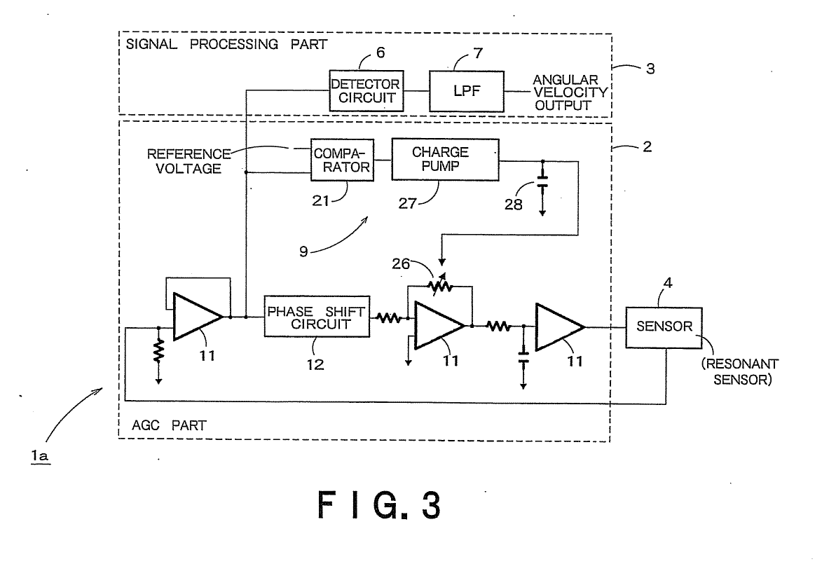

FIG. 3 is a block diagram of a sensor system is that is a comparative example to the sensor system 1 of FIG. 1. The sensor system is of FIG. 3 is different from the sensor system 1 of FIG. 1 in that the former does not have the digital processing part 22 and the switched capacitor 13. Connected to one of the cascade-connected buffers 11 in an autonomous-oscillation loop part 8 of FIG. 3 is a variable resistor 26 instead of the switched capacitor 13. The resistance of the variable resistor 26 is adjusted by a control signal output from an automatic adjustment loop part 9.

The automatic adjustment loop part 9 of FIG. 3 has a charge pump 27 instead of the digital processing part 22. The charge pump 27 converts a differential signal detected by a comparator 21 into a voltage signal. A capacitor 28 is connected between an output terminal of the charge pump 27 and a ground terminal. An output impedance of the charge pump 27 and the capacitor 28 constitute an analog low-pass filter.

The automatic adjustment loop part 9 performs control to make constant the amplitude of a carrier signal. The band to be controlled by the automatic adjustment loop part 9 has to be lower than the frequency of the carrier signal. Therefore, in the automatic adjustment loop part 9 of FIG. 3, a large time constant CR is given by the output impedance of the charge pump 27 and the capacitor 28, hence inevitably requires a large circuit area.

The DLPF 24 of FIG. 1 described above is configured to exhibit the same filtering characteristics as the analog low-pass filter constituted by the output impedance of the charge pump 27 and the capacitor 28 of FIG. 3. The DLPF 24 of FIG. 1 obtains a low-frequency control band by digital signal processing, hence not requiring such a large time constant CR in FIG. 3. Accordingly, a smaller circuit area can be achieved with the DLPF 24 of FIG. 1.

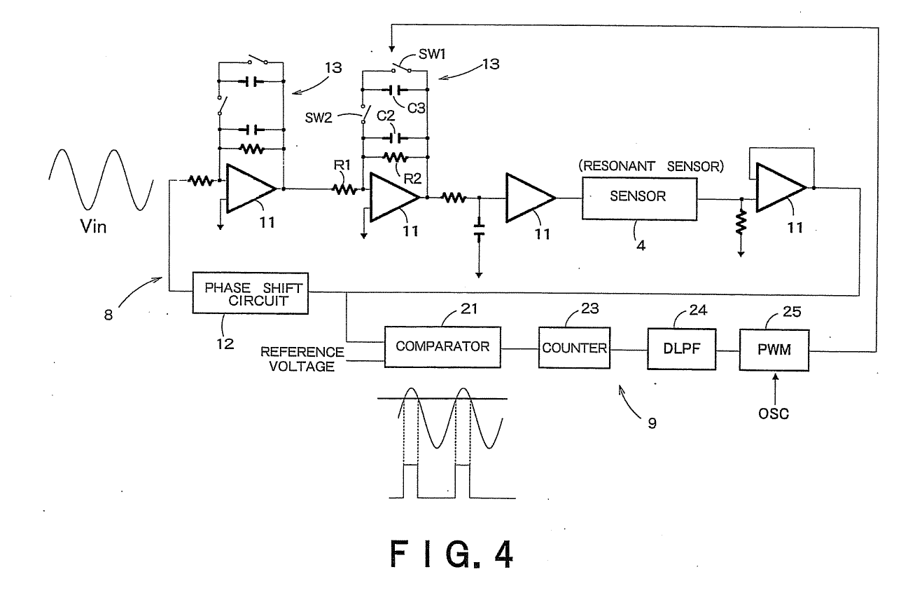

FIG. 4 is a block diagram showing more in detail the internal configuration of the AGC part 2 of FIG. 1. FIG. 4 shows an example in which an autonomous-oscillation loop part 8 in an AGC part 2 has four cascade-connected buffers 11, each of two buffers 11 having a switched capacitor 13. A larger number of buffers 11 connected with switched capacitors 13 gives a wider range for gain adjustments, thus enhancing the dynamic range. Nevertheless, it is preferable that at least one of the cascade-connected buffers 11 has a switched capacitor 13, hence FIG. 4 being just an example. Moreover, any number of buffers 11 can be connected in cascade in the autonomous-oscillation loop part 8.

The switched capacitors 13 shown in FIG. 4 have basically the same configuration as the switched capacitor 13 of FIG. 2(b). The difference of the switched capacitors 13 of FIG. 4 from FIG. 2(b) is that a resistor R2 is connected between the input and output terminals of each buffer 11.

As indicated by the expression (1) described above, a higher switching frequency f of the switches SW1 and SW2 in the switched capacitor 13 gives a lower impedance R to the switched capacitor 13. The switched capacitor 13 is connected between the input and output terminals of a buffer 11. Therefore, as indicated by the expression (2) described above, a higher impedance R of the switched capacitor 13 gives a higher gain to the buffer 11. That is, a higher switching frequency f of the switches SW1 and SW2 gives a lower gain to the buffer 11 whereas a lower switching frequency f gives a higher gain to the buffer 11.

Accordingly, fine control of the switching frequency f of the switches SW1 and SW2 offers fine control of the gain of the buffer 11.

The switches SW1 and SW2 in the switched capacitor 13 are turned on or off by a control signal output from the PWM circuit 25 in the digital processing part 22. In the present embodiment, the digital processing part 22 generates a control signal with which fine control is achieved for the switching frequency f of the switches SW1 and SW2. Explained in detail hereinbelow is an operation of the digital processing part 22.

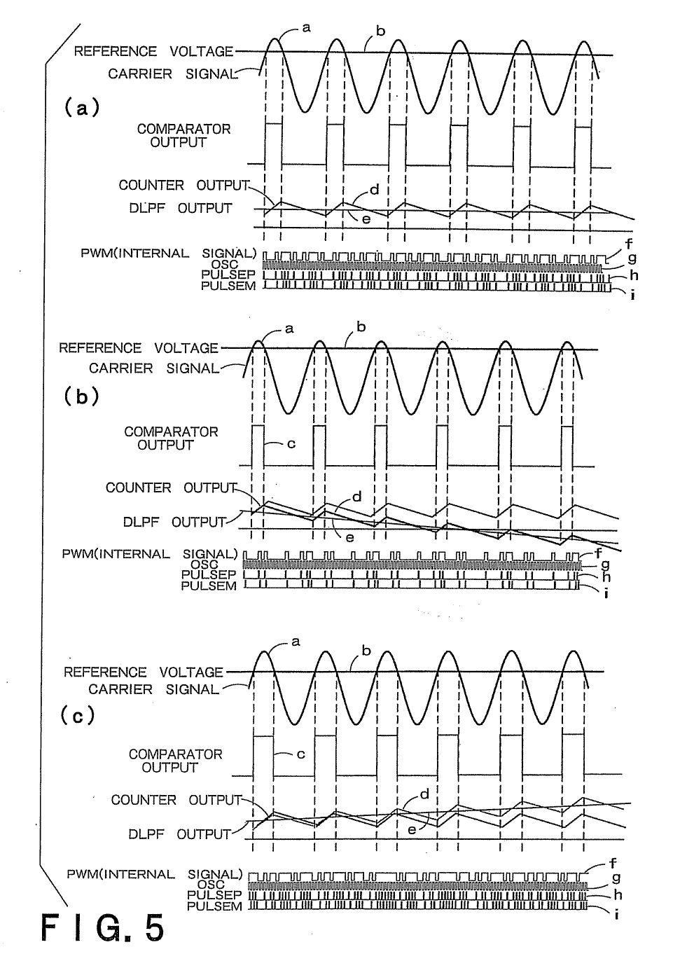

FIG. 5 shows signal waveforms at several sections in the digital processing part 22. FIGS. 5(a), 5(b), and 5(c) show signal waveforms in the case where the amplitude of a carrier signal is equal to, smaller than, and larger than a specific value, respectively.

The comparator 21 compares a carrier signal and a reference voltage level and outputs a pulse signal indicated by a waveform c in FIG. 5 when the former is larger than the latter. When the carrier signal is larger than the reference voltage level, or while the comparator 21 is outputting the pulse signal, the counter 23 continues count-up. On the other hand, when the carrier signal is equal to or smaller than the reference voltage level, or while the comparator 21 is not outputting the pulse signal, the counter 23 continues count-down. Therefore, as shown by a waveform d in FIG. 5, the counter 23 outputs a sawtooth waveform d. The counter 23 outputs a digital value that actually has a jagged waveform having a level varying step by step. However, at a very high clock frequency, the counter 23 practically outputs a sawtooth waveform such as shown in FIG. 5.

The output signal waveform d of the counter 23 will be explained in detail. When the amplitude of the carrier signal is equal to a reference value, the output signal of the counter 23 has a waveform with a period of liner increase and a period of liner decrease that alternately appear with a specific reference voltage level, as shown in FIG. 5(a). When the amplitude of the carrier signal is smaller than the reference value, the output signal of the counter 23 has a waveform with a period of liner increase and a period of liner decrease that alternately appear with a reference voltage level that linearly decreases as time passes, as shown in FIG. 5(b). When the amplitude of the carrier signal is larger than the reference value, the output signal of the counter 23 has a waveform with a period of liner increase and a period of liner decrease that alternately appear with a reference voltage level that linearly increases as time passes, as shown in FIG. 5(c).

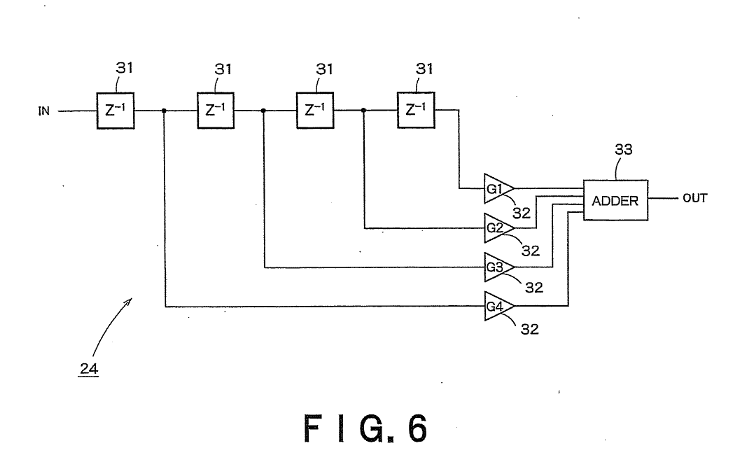

The DLPF 24, that exhibits the same characteristics as an analog low-pass filter, generates a signal by smoothing the output signal of the counter 23 for a specific period. FIG. 6 is a block diagram showing an example of the internal configuration of the DLPF 24. The DLPF 24 of FIG. 6 has four delay circuits 31 connected in series, buffers 32 each performing gain adjustments for the output signal of the corresponding delay circuit 31, and an adder 33 for adding the output signals of the buffers 32.

The DLPF 24 of FIG. 6 adds the output signals of the counter 23 at the adder 33 for a specific period that is the total of delay times of the four delay circuits 31. The adder 33 outputs a signal that is a smoothed output signal of the counter 23. Accordingly, as indicated by a waveform e in FIG. 5, the output signal of the DLPF 24 has a constant voltage level, a linearly increased voltage level or a linearly decreased voltage level.

In more detail, when the amplitude of the carrier signal is equal to a reference value, the output signal of the DLPF 24 has a constant voltage level, as shown in FIG. 5(a). When the amplitude of the carrier signal is smaller than the reference value, the output signal of the DLPF 24 has a voltage level that linearly decreases as time passes, as shown in FIG. 5(b). When the amplitude of the carrier signal is larger than the reference value, the output signal of the DLPF 24 has a voltage level that linearly increases as time passes, as shown in FIG. 5(c).

The output signal of the DLPF 24 is input to the PWM circuit 25. Based on the output signal of the DLPF 24, the PWM circuit 25 internally generates PWM pulse signals having various pulse widths (a waveform f in FIG. 5). The PWM pulse signals are an internal signal of the PWM circuit 25, hence not output to the outside. The PWM circuit 25 determines a time of appearance and a pulse width of each PWM pulse signal so that the PWM pulse signals appear at an equal rate in one period of the output signal of the DLPF 24.

Next, the PWM circuit 25 generates control signals each being a pulse signal having a constant pulse width (waveforms h and i in FIG. 5) for the a pulse output period of the PWM pulse signals, based on an oscillating signal OS (a waveform g in FIG. 5). A wider pulse width of the PWM pulse signals gives a larger number of pulse signals contained in the control signals. A control signal PULSEP indicated with the waveform h is used for switching of the switch SW1. A control signal PULSEM indicated with the waveform i is used for switching of the switch SW2. These control signals PULSEP and PULSEM are out of phase with each other to turn on or off the switches SW1 and SW2 with different on periods without overlapping each other.

In this way, the number of pulse signals contained in the control signals is smaller in the case where the amplitude of the carrier signal is smaller than the specific value than case where the former is equal to the latter. On the other hand, the number of pulse signals contained in the control signals is larger in the case where the amplitude of the carrier signal is larger than the specific value than case where the former is equal to the latter.

A larger number of pulse signals contained in the control signals mean a higher switching frequency f of the switches SW1 and SW2 of the switched capacitor 13. A higher switching frequency f gives a lower impedance R to the switched capacitor 13. This results in a lower gain of the buffer 11 to which the switched capacitor 13 is connected, hence a smaller amplitude of the carrier signal. This further results in a smaller number of pulse signals contained in the control signals.

Conversely, a smaller number of pulse signals contained in the control signals mean a lower switching frequency f of the switches SW1 and SW2 of the switched capacitor 13. A lower switching frequency f gives a higher impedance R to the switched capacitor 13. This results in a higher gain of the buffer 11 to which the switched capacitor 13 is connected, hence a larger amplitude of the carrier signal. This further results in a larger number of pulse signals contained in the control signals.

As described above, the automatic adjustment loop part 9 increases or decreases the number of pulse signals in the control signals in accordance with a result of comparison between the amplitude of the carrier signal and a reference voltage level for varying the switching frequency f of the switched capacitor 13, thus adjusting the gain of the buffer 11. What is achieved here is, therefore, feedback control that makes the amplitude of the carrier signal equal to a reference value.

Provided to be the PWM circuit 25 as an actual configuration is a ΔΣD/A converter that can accurately set an average frequency in a low band of the switching frequency of the switches for highly accurate amplitude settings.

Explained below is the reason why the PWM circuit 25 does not output the PWM pulse signals generated as an internal signal but outputs pulse signals, the number of which corresponds to the pulse width of the PWM pulse signals, in the present embodiment. The reason for this is to control the switching frequency f of the switches SW1 and SW2 for adjustment to the gain of the buffer 11. The control of the switching frequency f requires to vary the number of pulse signals output from the PWM circuit 25. Outputting a signal with just varying its pulse width cannot control the switching frequency f. Accordingly, in the present embodiment, the pulse widths of the PWM pulse signals are replaced with the number of pulse signals for control of the switching frequency f of the switched, capacitor 13 in accordance with the number of pulse signals.

Explained next is an operation of the sensor system 1 according to the present embodiment. The autonomous-oscillation loop part 8 in the AGC part 2 performs feedback control in a manner that the frequency of a carrier signal becomes equal to that of a sensor-detected signal output from the sensor 4. With the operation of the autonomous-oscillation loop part 8, the sensor-detected signal is superposed on the carrier signal.

However, the sensor-detected signal may not always be in phase with the carrier signal. The sensor-detected signal may be superposed on the carrier signal with a given phase difference (for example, 90 degrees). In this specification, the sensor-detected signal superposed on the carrier signal is referred to as a sensor-modulated signal.

A sensor-modulated signal is input to the detector circuit 6 in the signal processing part 3 shown in FIG. 1 to remove a carrier-signal component. The signal having the carrier-signal component removed is then input to the low-pass filter 8 to remove a high-frequency noise to extract the original sensor-detected signal which is an angular velocity signal, for example.

While the operation described above is performed, a carrier signal generated by the autonomous-oscillation loop part 8 is input to the comparator 21 in the automatic adjustment loop part 9. The comparator 21 compares the amplitude of the carrier signal and a reference voltage level and outputs pulse signals for a period in which the former is larger than the latter (the waveform c in FIG. 5).

The pulse signals are input to the digital processing part 22 to be processed digitally to generate control signals. Controlled with the control signals is the gain of the buffer 11 in the autonomous-oscillation loop part 8.

The operation of the digital processing part 22 is explained in more detail. Based on the pulse signals output from the comparator 21, the counter 23 performs count-up when the amplitude of the carrier signal is equal to or larger than a reference voltage level whereas performs count-down when the former is smaller than the latter, to generate a count signal (the waveform d in FIG. 5).

Next, the DLPF 24 smoothes the count signal for a specific period to generate a smoothed signal (the waveform e in FIG. 5). Based on the signal generated by the DLPF 24, the PWM circuit 25 generates PWM pulse signals as an internal signal and then generates control signals each having a pulse signal with a constant pulse width, with replacement of pulse widths of the PWM pulse signals with a specific number of pulses. The control signals are used for controlling the switching frequency of the switched capacitor 13 connected to the buffer 11 in the autonomous-oscillation loop part 8. This results in fine control of the gain of the buffer 11.

As described above, in the present embodiment, the control is performed to make constant the amplitude of a carrier signal on which a sensor-detected signal is superposed. In order to achieve this control, the digital processing part 22 and the switched capacitor 13 are provided so that the former controls the switching frequency f of the latter. With this control, highly accurate and fine adjustment is achieved for the gain of the buffer 11 to which the switched capacitor 13 is connected.

Moreover, the gain adjustment at the switched capacitor 13 keeps the linearity of signals in a wide dynamic range.

Furthermore, it is required to operate the automatic adjustment loop part 9 in a lower frequency band than the autonomous-oscillation loop part 8. For this reason, when an analog low-pass filter is constituted by the charge pump 27 and the capacitor 28, as shown in FIG. 3, for example, a capacitor 28 of a large capacitance is required to have a large time constant CR. Different from this, in the present embodiment, digital signal processing is performed by the digital processing part 22 provided in the automatic adjustment loop part 9. Therefore, the present embodiment does not require a large time constant CR, hence the automatic adjustment loop part 9 can be formed in a small circuit area, thus easily being formed into a semiconductor ship.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A sensor control circuit comprising:
an autonomous-oscillation loop part configured to generate a sensor-modulated signal having a carrier signal and an alternating signal output by a sensor and superposed on the carrier signal having the same frequency as the alternating signal; and
an amplitude adjustment loop part configured to generate a control signal for amplitude adjustment of the carrier signal, by digital processing of a result of comparison between the carrier signal and a reference voltage level,
wherein the autonomous-oscillation loop part comprises:
an amplifier configured to perform amplitude adjustment of the carrier signal; and
a switched capacitor having a switch configured to be switched by the control signal, the switched capacitor configured to be capable of controlling a gain of the amplifier in accordance with a switching frequency of the switch.

2. The sensor control circuit in claim 1, wherein the amplitude adjustment loop part generates the control signal so that the carrier signal has a constant amplitude.

3. The sensor control circuit in claim 1, wherein
the amplitude adjustment loop part increases or decreases the number of pulse signals included in the control signal in accordance with a difference between an amplitude of the carrier signal and the reference voltage level,
the switching frequency of the switch is varied and an impedance of the switched capacitor is adjusted, in accordance with increase or decrease in the number of pulse signals included in the control signal, and
the gain of the amplifier is adjusted in accordance with the impedance of the switched capacitor.

4. The sensor control circuit in claim 1, wherein the amplitude adjustment loop part comprises:
a comparator configured to compare an amplitude of the carrier signal and the reference voltage level;
a counter configured to count up while the amplitude of the carrier signal is equal to or larger than the reference voltage level and count down while the amplitude of the carrier signal is smaller than the reference voltage level, based on a result of comparison at the comparator, thus generating a count value;
a digital filter configured to generate a digital smoothed signal by averaging the count value for a specific period; and
a pulse-width modulation circuit configured to generate the control signal based on the digital smoothed signal.

5. The sensor control circuit in claim 4, wherein the pulse-width modulation circuit generates the control signal that contains a specific number of pulse signals having a constant pulse width, the specific number corresponding to a result of comparison at the comparator.

6. The sensor control circuit in claim 5, wherein the pulse-width modulation circuit generates a pulse-width-modulated signal having a pulse width that varies in accordance with the digital smoothed signal for each period of the digital smoothed signal and generates the control signal containing the specific number of pulse signals, the specific number corresponding to the pulse width of the pulse-width-modulated signal.

7. The sensor control circuit in claim 5, wherein the pulse-width modulation circuit generates the control signal, the number of the pulse signals of the control signal being larger as a period at which the amplitude of the carrier signal is equal to or larger than the reference voltage is longer.

8. The sensor control circuit in claim 5, wherein the gain of the amplifier is lowered as the specific number of pulse signals is larger.

9. The sensor control circuit in claim 1, wherein the autonomous-oscillation loop part has a plurality of buffers, a phase shifter, and the sensor connected to one another in a ring shape,
wherein at least one of the buffers is the amplifier to which the switched capacitor is connected.

10. The sensor control circuit in claim 1, wherein the sensor is an angular velocity sensor that detects an angle and outputs an oscillating signal.

11. A sensor system comprising:
a sensor configured to output an alternating signal that is a result of detection of an object;
a sensor control circuit configured to output a sensor-modulated signal having a carrier signal and the alternating signal superposed on the carrier signal; and
a signal processing part configured to remove the carrier signal from the sensor-modulated signal to extract the alternating signal,
wherein the sensor control circuit comprises:
an autonomous-oscillation loop part configured to generate the sensor-modulated signal having the carrier signal and the alternating signal superposed on the carrier signal having the same frequency as the alternating signal; and
an amplitude adjustment loop part configured to generate a control signal for amplitude adjustment of the carrier signal, by digital processing of a result of comparison between the carrier signal and a reference voltage level,
wherein the autonomous-oscillation loop part comprises:
an amplifier configured to perform amplitude adjustment of the carrier signal; and
a switched capacitor having a switch configured to be switched by the control signal, the switched capacitor configured to be capable of controlling a gain of the amplifier in accordance with a switching frequency of the switch.

12. The sensor system in claim 11, wherein the amplitude adjustment loop part generates the control signal so that the carrier signal has a constant amplitude.

13. The sensor system in claim 11, wherein
the amplitude adjustment loop part increases or decreases the number of pulse signals included in the control signal in accordance with a difference between an amplitude of the carrier signal and the reference voltage level,
the switching frequency of the switch is varied and an impedance of the switched capacitor is adjusted, in accordance with increase or decrease in the number of pulse signals included in the control signal, and
the gain of the amplifier is adjusted in accordance with the impedance of the switched capacitor.

14. The sensor system in claim 11, wherein the amplitude adjustment loop part comprises:
a comparator configured to compare an amplitude of the carrier signal and the reference voltage level;
a counter configured to count up while the amplitude of the carrier signal is equal to or larger than the reference voltage level and count down while the amplitude of the carrier signal is smaller than the reference voltage level, based on a result of comparison at the comparator, thus generating a count value;
a digital filter configured to generate a digital smoothed signal by averaging the count value for a specific period; and
a pulse-width modulation circuit configured to generate the control signal based on the digital smoothed signal.

15. The sensor system in claim 14, wherein the pulse-width modulation circuit generates the control signal that contains a specific number of pulse signals having a constant pulse width, the specific number corresponding to a result of comparison at the comparator.

16. The sensor system in claim 15, wherein the pulse-width modulation circuit generates a pulse-width-modulated signal having a pulse width that varies in accordance with the digital smoothed signal for each period of the digital smoothed signal and generates the control signal containing the specific number of pulse signals, the specific number corresponding to the pulse width of the pulse-width-modulated signal.

17. The sensor system in claim 15, wherein the pulse-width modulation circuit generates the control signal, the number of the pulse signals of the control signal being larger as a period at which the amplitude of the carrier signal is equal to or larger than the reference voltage is longer.

18. The sensor system in claim 15, wherein the gain of the amplifier is lowered as the specific number of pulse signals is larger.

19. The sensor system in claim 11, wherein the autonomous-oscillation loop part has a plurality of buffers, a phase shifter, and the sensor connected to one another in a ring shape,
wherein at least one of the buffers is the amplifier to which the switched capacitor is connected.

20. The sensor system in claim 11, wherein the sensor is an angular velocity sensor that outputs an oscillating signal.
